(19) United States
(12) Patent Application Publication
(10) Pub. No.: US 2007/0099363 A1
(43) Pub. Date: May 3, 2007

(54) Method of manufacturing semiconductor device

(76) Inventor: Kazuaki Nakajima, Kamakura-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/520,827

(22) Filed: Sep. 14, 2006

(30) Foreign Application Priority Data
Sep. 28, 2005 (JP) 2005-281340

(51) Int. Cl. H01L 21/8234; H01L 21/336

(52) U.S. Cl. 438/197

(57) ABSTRACT

There are provided steps of: forming a gate insulating film on a semiconductor substrate; sequentially forming a first gate electrode material film, a first insulating film, a second gate electrode material film, which is thinner than the first gate electrode material film, on the gate insulating film, and patterning these films and the gate insulating film, thereby forming a gate electrode; forming a first metal film at least on the second gate electrode material film of the gate electrode and causing the first metal film to react, thereby changing the second gate electrode material film of the gate electrode to a first reaction layer; removing the first reaction layer on the gate electrode; forming an interlayer insulating film on the entire surface and flattening the interlayer insulating film until the first gate electrode material film of the gate electrode is exposed; forming a second metal film on the entire surface and causing the second metal film to react with the first gate electrode material film of the gate electrode, thereby chanting the first gate electrode material film to a second reaction layer until the second reaction layer contacts the gate insulating film.

### CROSS-REFERENCE TO RELATED APPLICATION

This application is based upon and claims the benefit of priority from prior Japanese Patent Application No. 2005-281340 filed on Sep. 28, 2005 in Japan, the entire contents of which are incorporated herein by reference.

### BACKGROUND OF THE INVENTION

1. Field of the Invention

The present invention relates to a method of manufacturing a semiconductor device including a MIS type transistor in which a conductor film is used to form a gate electrode.

2. Background Art

Conventionally, miniaturization of devices has been sought in order to improve the performance of MOSFETs. However, devices in the 0.1 μm or later generation are said to have a limit in scaling of gate oxide film. The reason for this is that as the thickness of a gate oxide film becomes thinner, the increase in gate leakage current caused by tunnel current becomes remarkable. Furthermore, in the aforementioned generations, the depletion in gate electrode cannot be ignored, and it is not possible to decrease the effective oxide thickness as expected.

In order to solve the aforementioned problems, the improve in dielectric constant of a gate insulating film or the use of a metal gate electrode are studied. The former method intends to curb the tunnel current by replacing the gate insulating film with a high-k film to increase the physical film thickness. The latter method intends to prevent the depletion of the gate electrode by metalizing the gate electrode.

In particular, recently, the development of high-k gate insulating film materials is actively performed. New materials such as ZrO₂ and HfO₂ are taken as a subject of academic conferences. The decrease in effective oxide thickness is sought. However, so far, such materials have not been developed successfully enough so that the reliability etc. of such materials can be argued as in the case of silicon oxide film. Accordingly, it is considered to take a long time to realize the commercial use of such materials.

As indicated in the 2003 version of ITRS (International Technology Roadmap for Semiconductor), it is said to be difficult to manufacture a transistor using a conventional electrode of polycrystalline silicon having a physical film thickness of less than 1.0 nm. The depletion in the gate electrode, when converted to the equivalent oxide thickness, is about 0.3 nm. In order to extend the life of silicon oxide films to this generation, it is necessary to develop metal gate electrodes. In particular, the fully-silicided electrode process is outstanding in matching property with respect to the conventional CMOS process, and the development thereof is accelerated.

When a MIS type transistor is manufactured which has a shallow diffusion layer serving as an extension layer and a deep diffusion layer in source and drain regions, and the gate electrode of which is fully silicided, the shallow diffusion layer may be formed first and the deep diffusion layer may be formed next.

However, when the shallow diffusion layer is formed first, at the time a heat treatment is performed during the formation of the deep diffusion layer, the distribution of the shallow diffusion layer may be elongated. In the 110 nm generation in which the gate length is on the order of 110 nm, the depth of the shallow diffusion layer needed is about 100 nm. Accordingly, the elongation of the shallow diffusion layer due to the heat treatment is not an important problem. However, in or after the 65 nm generation, the depth of the diffusion layer needed is about 50 nm, and in the worst case, the shallow diffusion layer may be connected with each other.

For the aforementioned reason, after the 65 nm generation, it is necessary to form the shallow diffusion layer after the deep diffusion layer. This technique to form the shallow diffusion layer after the deep diffusion layer to manufacture a MIS type transistor is known (for example, U.S. Pat. No. 6,309,937). In the technique disclosed in this patent publication, although a silicide layer is formed on a deep diffusion layer and a gate electrode of polycrystalline silicon, the gate electrode is not fully silicided.

In order to form a fully silicided gate electrode, after a silicide layer is formed on the deep diffusion layer and the gate electrode of polycrystalline silicon, an interlayer insulating film is deposited on the entire surface, and then the interlayer insulating film is flattened by the chemical mechanical polishing (CMP) until the surface of the gate electrode is exposed. Subsequently, a Ni film, for example, is deposited on the entire surface, and a heat treatment is performed, thereby forming a fully silicided gate electrode.

In this case, since a silicide layer has already been formed on the gate electrode, the silicidation of all the gate electrode is performed through this silicide layer. At this time, if the surface of the silicide layer on the gate electrode is oxidized, Ni atoms cannot be diffused, thereby inhibiting the silicidation reaction. Therefore, the cleaning of the surface of the gate electrode is important. However, the silicide layer can dissolve in a chemical solution containing HF etc., and the oxide on the silicide layer is not a simple silicon oxide but a film containing metal oxide. Therefore, it is difficult to sufficiently clean the surface of the silicide layer. As a result, the silicidation reaction cannot be uniformly performed, and the imbalance in film thickness of the silicides layer of the gate electrode becomes greater. Therefore, metal silicide and polycrystalline silicon are mixed in the gate electrode.

During the aforementioned process of flattening the interlayer insulating film, when the silicide layer on the gate electrode is exposed, it is likely that the silicide layer is dissolved or oxidized by the abrasive agent. On the contrary, if the metal in the silicide layer is not dissolved by the abrasive agent, not only the wafer but also the polishing device itself may be contaminated by the metal.

Therefore, it is necessary to provide a new method of manufacturing a MIS type transistor including a deep diffusion layer and a shallow diffusion layer to form source and drain regions, and a gate electrode of a metal silicide.

### SUMMARY OF THE INVENTION

The present invention proposes a method of manufacturing a semiconductor device including a MIS type transistor having deep diffusion layer and a shallow diffusion layer to form source and drain regions, and a gate electrode of a metal silicide.

A method of manufacturing a semiconductor device according to a first aspect of the present invention includes:

forming a gate insulating film on a semiconductor substrate;

sequentially forming a first gate electrode material film, a first insulating film, and a second gate electrode material film, which is thinner than the first gate electrode material film, on the gate insulating film, and patterning these films and the gate insulating film to form a gate electrode;

forming a first sidewall of an insulating material at a side portion of the gate electrode;

forming a first diffusion layer in the semiconductor substrate at both sides of the gate electrode by implanting ions of an impurity using the gate electrode and the first sidewall as masks;

removing the first sidewall, and then forming a second sidewall of an insulating material, which is thinner than the first sidewall, at the side portion of the gate electrode;

forming a second diffusion layer in the semiconductor substrate at both sides of the gate electrode by implanting ions of an impurity using the gate electrode and the second sidewall as masks;

changing the second gate electrode material film of the gate electrode to a first reaction layer by forming a first metal film at least on the second gate electrode material film of the gate electrode and causing the first metal film to react with the second gate electrode material film;

removing the first reaction layer on the gate electrode;

forming an interlayer insulating film on the entire surface, and then flattening the interlayer insulating film until an upper surface of the first gate electrode material film of the gate electrode is exposed; and

forming a second metal film on the entire surface and causing the second metal film to react with the first gate electrode material film of the gate electrode, thereby changing the first gate electrode material film to a second reaction layer until the second reaction layer contacts the gate insulating film.

A method of manufacturing a semiconductor device according to a second aspect of the present invention includes:

forming a p-type well and an n-type well, which are element isolated, in a semiconductor substrate;

forming a first gate insulating film and a second gate insulating film on the p-type well and the n-type well, respectively;

forming a first gate electrode material film on the first and the second gate insulating films;

implanting an n-type impurity into the first gate electrode material film on the first gate insulating film, and implanting a p-type impurity into the first gate electrode material film on the second gate insulating film;

sequentially forming a first insulating film and a second gate electrode material film, which is thinner than the first gate electrode material film, on the first gate electrode material film, and patterning the second gate electrode material film, the first insulating film, the first gate electrode material film, and the gate insulating film, thereby forming a first gate electrode on the p-type well and forming a second gate electrode on the n-type well;

forming first sidewalls of an insulating material on side portions of the first and the second gate electrodes;

implanting ions of an n-type impurity using the first gate electrode and the first sidewall as masks, thereby forming a first diffusion layer of an n-type at both sides of the first gate electrode in the semiconductor substrate;

implanting ions of a p-type impurity using the second gate electrode and the first sidewall as masks, thereby forming a second diffusion layer of a p-type at both sides of the second gate electrode in the semiconductor substrate;

removing the first sidewall, and forming second sidewalls of an insulating material, which are thinner than the first sidewalls, at side portions of the first and the second gate electrodes;

implanting ions of an n-type impurity using the first gate electrode and the second sidewall as masks, thereby forming a third diffusion layer of an n-type at both sides of the first gate electrode in the semiconductor substrate;

implanting ions of a p-type impurity using the second gate electrode and the second sidewall as masks, thereby forming a fourth diffusion layer of a p-type at both sides of the second gate electrode in the semiconductor substrate;

forming a first metal film at least on the second gate electrode material film of the first and the second gate electrodes and causing the first metal film to react with the second gate electrode material film, thereby changing the second gate electrode material film of the first and the second gate electrodes to a first reaction layer;

removing the first reaction layer on the first and the second gate electrodes;

forming an interlayer insulating film on the entire surface, and flattening the interlayer insulating film until an upper surface of the first gate electrode material film of the first and the second gate electrodes is exposed; and

forming a second metal film on the entire surface, and causing the second metal film to react with the first gate electrode material film of the first and the second gate electrodes, thereby changing the first gate electrode material film to a second reaction layer to until the second reaction layer contacts the gate insulating film.

A method of manufacturing a semiconductor device according to a third aspect of the present invention includes:

forming a first semiconductor region and a second semiconductor region, which are element isolated, in a semiconductor substrate;

forming a first gate insulating film and a second gate insulating film on the first semiconductor region and the second semiconductor region, respectively;

sequentially forming a first gate electrode material film, a first insulating film, and a second gate electrode material film, which is thinner than the first gate electrode material film, on the first and the second gate insulating films;

patterning the second gate electrode material film and the first insulating film, thereby forming a pattern in an electrode shape including the second gate electrode material film and the first insulating film only on the first semiconductor region;

patterning the first gate electrode material film and the gate insulating film, thereby forming a first gate electrode including the second gate electrode material film, the first insulating film, the first gate electrode material film, and the gate insulating film on the first semiconductor region and forming a second gate electrode including the first gate electrode material film and the gate insulating film on the second semiconductor region;

forming first sidewalls of an insulating material at side portions of the first and the second gate electrodes;

implanting impurity ions using the first and the second gate electrodes and the first sidewalls as masks, thereby forming a first diffusion layer at both sides of the first and the second gate electrodes in the semiconductor substrate;

removing the first sidewalls, and forming second sidewalls of an insulating material, which are thinner than the first sidewalls, at side portions of the first and the second gate electrodes;

implanting ions of an n-type impurity using the first gate electrode and the second sidewall as masks, thereby forming a second diffusion layer at both sides of the first and the second gate electrodes in the semiconductor substrate;

forming a first metal film at least on the second gate electrode material film of the first gate electrode and the first electrode material film of the second gate electrode and causing the first metal film to react, thereby changing the second gate electrode material film of the first gate electrode to a first reaction layer and forming a second reaction layer on the first electrode material film of the second gate electrode;

removing the first reaction layer on the first gate electrode;

forming a second insulating film on the first and the second gate electrodes;

forming an interlayer insulating film on the entire surface, and flattening the interlayer insulating film until an upper surface of the first gate electrode material film of the first gate electrode is exposed in the first semiconductor region and the second insulating film on the second gate electrode is exposed in the second semiconductor region; and

forming a second metal film on the entire surface, and causing the second metal film to react with the first gate electrode material film of the first gate electrode so that the first gate electrode material film is changed to a third reaction layer until the third reaction layer contacts the gate insulating film.

### BRIEF DESCRIPTION OF THE DRAWINGS

FIG. 1 is a sectional view showing a step of a method of manufacturing a semiconductor device according to a first embodiment of the present invention.

FIG. 2 is a sectional view showing a step of the method of manufacturing a semiconductor device according to the first embodiment of the present invention.

FIG. 3 is a sectional view showing a step of the method of manufacturing a semiconductor device according to the first embodiment of the present invention.

FIG. 4 is a sectional view showing a step of the method of manufacturing a semiconductor device according to the first embodiment of the present invention.

FIG. 5 is a sectional view showing a step of the method of manufacturing a semiconductor device according to the first embodiment of the present invention.

FIG. 6 is a sectional view showing a step of the method of manufacturing a semiconductor device according to the first embodiment of the present invention.

FIG. 7 is a sectional view showing a step of the method of manufacturing a semiconductor device according to the first embodiment of the present invention.

FIG. 8 is a sectional view showing a step of the method of manufacturing a semiconductor device according to the first embodiment of the present invention.

FIG. 9 is a sectional view showing a step of the method of manufacturing a semiconductor device according to the first embodiment of the present invention.

FIG. 10 is a sectional view showing a step of a method of manufacturing a semiconductor device according to a second embodiment of the present invention.

FIG. 11 is a sectional view showing a step of the method of manufacturing a semiconductor device according to the second embodiment of the present invention.

FIG. 12 is a sectional view showing a step of the method of manufacturing a semiconductor device according to the second embodiment of the present invention.

FIG. 13 is a sectional view showing a step of the method of manufacturing a semiconductor device according to the second embodiment of the present invention.

FIG. 14 is a sectional view showing a step of the method of manufacturing a semiconductor device according to the second embodiment of the present invention.

FIG. 15 is a sectional view showing a step of the method of manufacturing a semiconductor device according to the second embodiment of the present invention.

FIG. 16 is a sectional view showing a step of the method of manufacturing a semiconductor device according to the second embodiment of the present invention.

FIG. 17 is a sectional view showing a step of the method of manufacturing a semiconductor device according to the second embodiment of the present invention.

FIG. 18 is a sectional view showing a step of the method of manufacturing a semiconductor device according to the second embodiment of the present invention.

FIG. 19 is a sectional view showing a step of the method of manufacturing a semiconductor device according to the second embodiment of the present invention.

FIG. 20 is a sectional view showing a step of the method of manufacturing a semiconductor device according to the second embodiment of the present invention.

### DESCRIPTION OF THE EMBODIMENTS

### First Embodiment

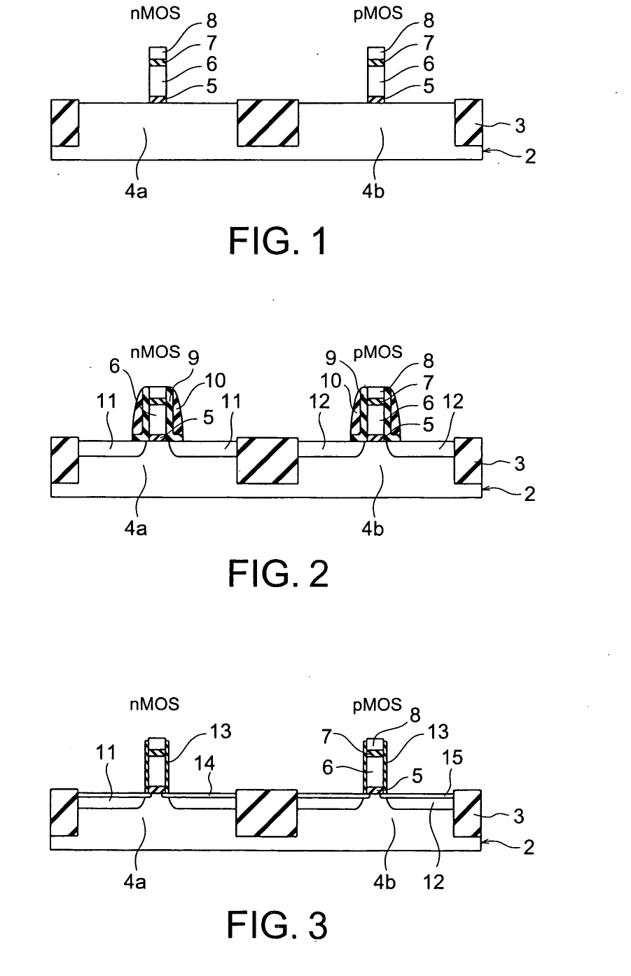

A method of manufacturing a semiconductor device according to a first embodiment of the present invention will be described in detail below with reference to FIGS. 1 to 9, which are sectional views showing steps of the method of manufacturing a semiconductor device according to the embodiment of the present invention.

First, as shown in FIG. 1, a p-type well 4a and an n-type well 4b are formed on a single crystal silicon substrate 2, which are isolated by an element isolation region 3. The p-type well becomes an n-type MOS transistor forming region, and the n-type well 4b becomes a p-type MOS transistor forming region. Subsequently, a gate insulating film 5 of, e.g., silicon oxynitride, is formed on the p-type well 4a and the n-type well 4b, and a polycrystalline silicon film 6 is deposited on the gate insulating film 5. Thereafter, arsenic ions (As⁺) are implanted into the polycrystalline silicon film 6 on the n-type MOS transistor forming regions 4a, and boron ions (B⁺) are implanted into the polycrystalline silicon film 6 on the p-type MOS transistor forming regions 4b. Furthermore, a thin insulating film 7 is deposited on the polycrystalline silicon film 6, and a thin polycrystalline silicon film 8 is deposited on the insulating film 7. Subsequently, a resist pattern (not shown) is formed on the polycrystalline silicon film 8, and anisotropy etching of the thin polycrystalline silicon film 8, the thin insulating film 7, the polycrystalline silicon film 6, and the gate insulating film 5 is performed using the resist pattern as a mask, thereby forming the gate electrode.

Next, as shown in FIG. 2, a silicon nitride film 9 and a silicon oxide film 10 are sequentially deposited on the entire surface, and etch back of the silicon oxide film 10 and the silicon nitride film 9 is performed, thereby obtaining a structure where only the side portions of the gate electrodes are surrounded by the sidewall composed of the silicon oxide film 10 and the silicon nitride film 9. Subsequently, for example, phosphorous ions (P⁺) are implanted into the n-type MOS transistor forming regions 4a, and boron ions (B⁺) are implanted into the p-type MOS transistor forming regions 4b and a heat treatment is performed at a temperature of 1,030° C. for five seconds, thereby forming deep diffusion layers 11 and 12.

Next, as shown in FIG. 3, the silicon oxide film 10 and the silicon nitride film 9 constituting the side portions of the gate electrodes are removed. Subsequently, a silicon nitride film 13 is deposited, and etch back of the silicon nitride film 13 is performed to leave the silicon nitride film 13 only at the side portions of the gate electrodes, thereby surrounding the side portions of the gate electrodes with the silicon nitride film 13. Thereafter, for example, As⁺ ions are implanted into the n-type MOS transistor forming regions 4a, and B⁺ ions are implanted into the p-type MOS transistor forming regions 4b, and a heat treatment is performed at a temperature of 800° C. for five seconds, thereby forming shallow diffusion layers 14 and 15.

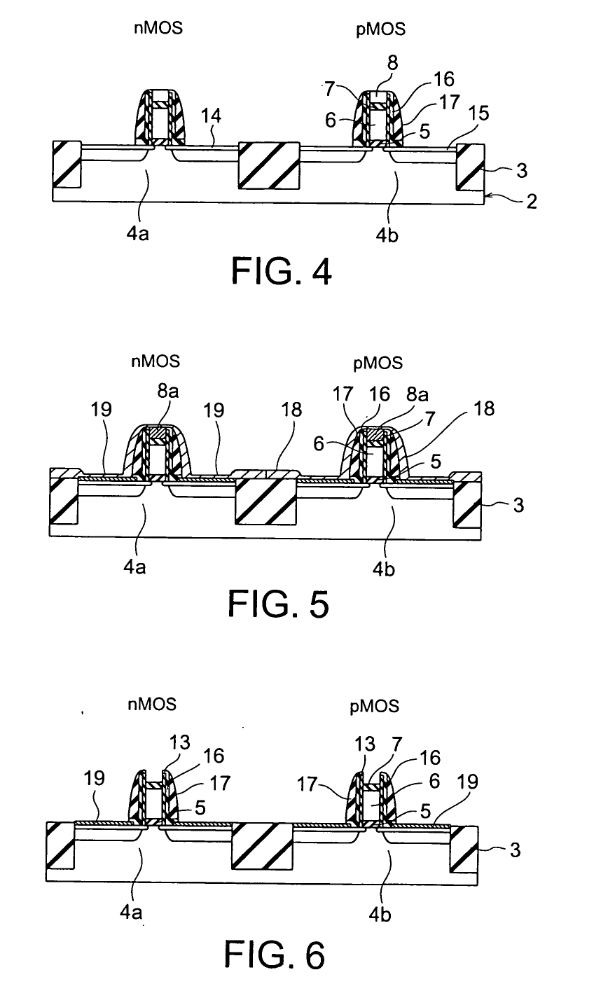

Then, as shown in FIG. 4, sidewalls composed of a silicon nitride film 16 and a silicon oxide film 17 are formed on the side portions of the gate electrodes.

Next, as shown in FIG. 5, for example, a nickel (Ni) film 18 having a film thickness of 10 nm is deposited on the entire surface, and a heat treatment is performed at a temperature of 350° C. for about 30 seconds, thereby causing Ni to react with the diffusion layer exposed on the silicon substrate and the polycrystalline silicon film 8 of the gate electrode to form silicide at the surface of the diffusion layer exposed on the silicon substrate and the polycrystalline silicon film 8 of the gate electrode. As a result, silicide layers 19 and 8a are formed. At this time, the silicide layer 8a is formed since the uppermost layer of the gate electrode is the thin polycrystalline silicon layer. If the film thickness of the polycrystalline silicon film 8 is 0.6 times the film thickness of the Ni film 18 or less, a metal-rich silicide layer 8a is formed in which the composition ratio of Ni/Si is 3 or more.

Then, as shown in FIG. 6, the unreacted Ni film is removed using, for example, a mixed solution of sulfuric acid and hydrogen peroxide. Thereafter, a heat treatment is performed at a temperature of 500° C. for 30 seconds. Since the aforementioned metal-rich silicide layer 8a can be dissolved into a mixed solution of, for example, sulfuric acid and hydrogen peroxide, the metal-rich silicide layer 8a on the gate electrode is removed. As a result, the silicide layer 19 is left only on the diffusion layer. The film thickness of the thin insulating film 7 can be, for example, 10 nm or less, with which it is possible to curb the diffusion of metal atoms.

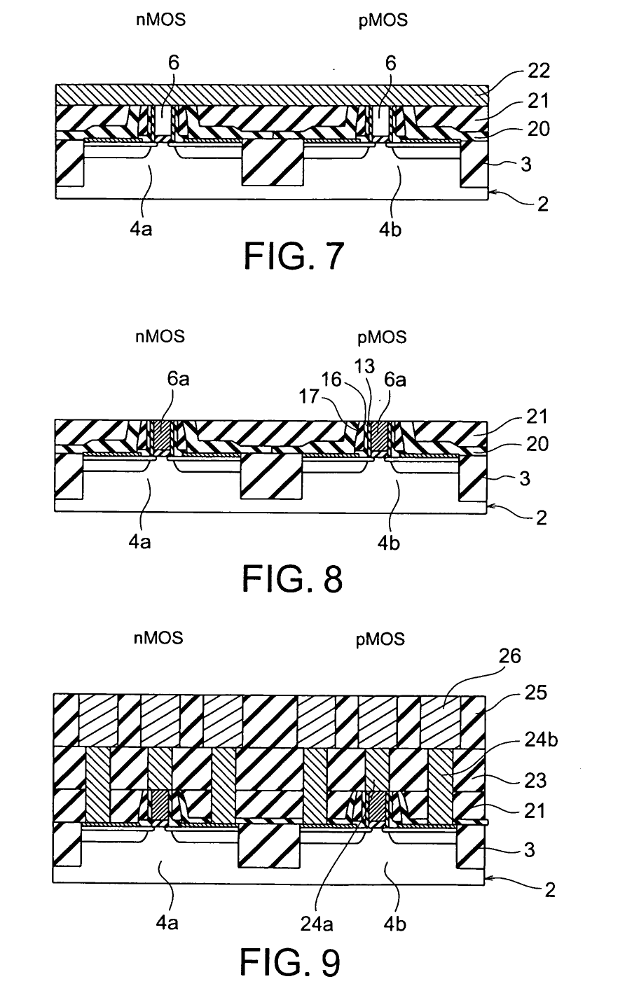

Subsequently, as shown in FIG. 7, a silicon nitride film 20 and an interlayer insulating film 21, for example, are deposited on the entire surface, and the interlayer insulating film 21 is flattened by, for example, chemical mechanical polishing (CMP) until the surface of the polycrystalline silicon 6 of the gate electrode is exposed. Then, a Ni film 22 having a film thickness of 60 nm, for example, is deposited on the entire surface.

Thereafter, as shown in FIG. 8, a heat treatment is performed at a temperature of, e.g., 350° C. for 30 seconds to cause the Ni film 22 and the polycrystalline silicon 6 to react with each other, and the unreacted portions of the Ni film 22 are removed by using, for example, a mixed solution of sulfuric acid and hydrogen peroxide. Then, a heat treatment is performed at a temperature of 400° C. for about 30 seconds, thereby changing the polycrystalline silicon layer 6 of the gate electrode to a Ni silicide layer 6a. At this time, the Ni silicide layer 6a is silicided to the portion contacting the gate insulating film 5, i.e., substantially fully silicided. There is no problem if a part of the side portions of the gate electrode is not silicided.

Subsequently, as shown in FIG. 9, an interlayer insulating film 23 is deposited on the entire surface, and contact holes connecting to the silicide layer 6a of the gate electrode and the silicide layer 19 on the diffusion layer are formed through the interlayer insulating film 23, the interlayer insulating film 21, and the silicon nitride film 20 using a lithography technique. A stacked layer of, e.g., titanium (Ti)/TiN/tungsten (W) is buried in the respective contact holes, and flattened by CMP, thereby forming contacts 24a and contacts 24b. Subsequently, an interlayer insulating film 25 is deposited on the entire surface and a desired groove pattern connecting to the contacts 24a and 24b is formed on the interlayer insulating film 25. Thereafter, a stacked layer of TaN/copper (Cu) is buried in the groove pattern and flattened by CMP, thereby forming Cu wiring 26 electrically connecting the contacts 24a and 24b.

With the aforementioned process, it is possible to form a CMOS transistor keeping the shallow diffusion layer but including uniformly formed silicide electrodes.

### Second Embodiment

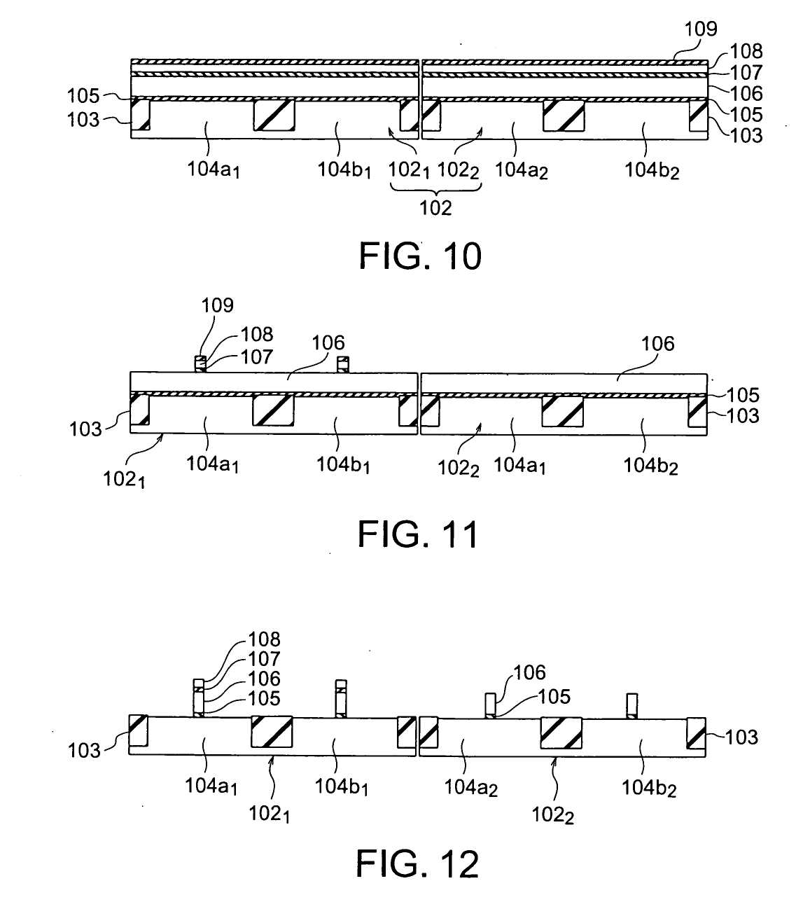

Next, a method of manufacturing a semiconductor device according to a second embodiment of the present invention will be described with reference to FIGS. 10 to 20, which are sectional views showing steps of the method of manufacturing a semiconductor device in this embodiment.

First, as shown in FIG. 10, a region 102₁ where the gate electrode should be metal-silicided (hereinafter also referred to as “FUSI formation region”) and a region 1022 or a salicide formation region where the gate electrode should not be metal-silicided (hereinafter also referred to as “non-FUSI formation region”), which are element isolated by element isolation regions 103, are formed on a single crystal silicon substrate 102. Thereafter, a p-type well 104a₁ and an n-type well 104b₁ which are element isolated by the element isolation regions 103 are formed in the FUSI formation region 102₁, and a p-type well 104a₂ and an n-type well 104b₂ which are element isolated by the element isolation regions 103 are formed in the non-FUSI formation region 1022.

Next, a silicon oxynitride film 105 serving as a gate insulating film is formed on the silicon substrate 102, and a polycrystalline silicon film 106 is deposited thereon. Thereafter, As⁺ ions are implanted into the polycrystalline silicon film 106 above the p-type wells 104a₁ and 104a₂, and B⁺ ions are implanted into the polycrystalline silicon film 106 above the n-type wells 104b₁ and 104b₂. Thereafter, a thin insulating film 107 is deposited on the polycrystalline silicon film 106, and furthermore, a thin polycrystalline silicon film 108 and an oxide film 109 are deposited thereon.

Then, in the FUSI formation region 102₁, a mask (not shown) of, e.g., a resist, in a shape of electrode is formed. Then, anisotropy etching is performed on the oxide film 109, the thin polycrystalline silicon film 108, the thin insulating film 107 using this mask, thereby forming a pattern in a shape of gate electrode (FIG. 11). At this time, in the non-FUSI formation region 102₂, the oxide film 109, the thin polycrystalline silicon film 108, and the thin insulating film 107 are removed by etching.

Subsequently, in the non-FUSI formation region 102₂, a mask (not shown) of, e.g., a resist, in a shape of electrode is formed. Then, anisotropy etching is performed on the polycrystalline silicon film 106 and the gate insulating film 105 using this mask. At this time, in the FUSI formation region 102₁, since the pattern including the oxide film 109, the polycrystalline silicon film 108, and the thin insulating film 107 has been formed, this pattern serves as an etching mask. Thus, gate electrode patterns are formed in both the FUSI formation region 102₁ and the non-FUSI formation region 102₂ (FIG. 12 ). The oxide film 109 may or may not be removed after the anisotropy etching since it disappears in the nest sidewall forming step. In FIG. 12, the oxide film 109 is removed.

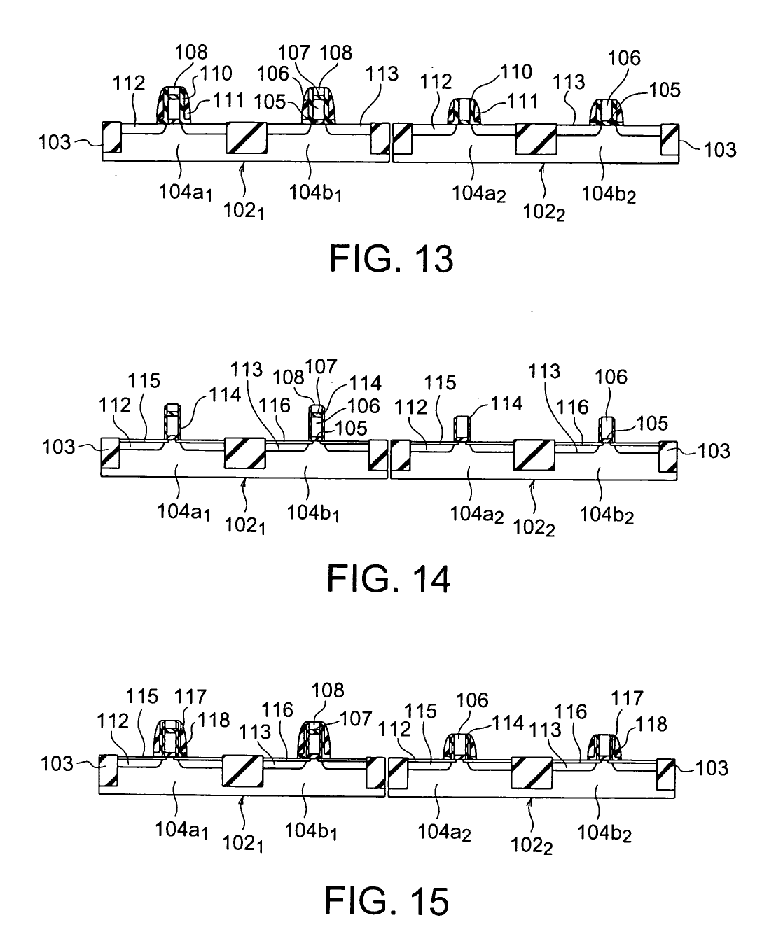

Next, as shown in FIG. 13, a silicon nitride film 110 and a silicon oxide film 111 are deposited, and etch back of the silicon oxide film 111 and the silicon nitride film 110 are performed, thereby obtaining a structure where sidewall portions of the electrode patterns are surrounded by the silicon nitride film 110 and the silicon oxide film 111. Furthermore, deep diffusion layers 112 and 113 are formed by implanting, for example, P⁺ ions into the p-type wells 104a₁ and 104a₂, and B⁺ ions into the n-type wells 104b₁ and 104b₂, and performing a heat treatment at a temperature of 1,030° C. for five seconds.

Next, as shown in FIG. 14, the silicon nitride film 110 and the silicon oxide film 111 at the sidewall portions of the electrode patterns are removed. Subsequently, a silicon nitride film 114 is deposited and etch back of the silicon nitride film 114 is performed, thereby obtaining a structure where the sidewall portions of the electrode patterns are surrounded by the silicon nitride film 114. Furthermore, shallow diffusion layers 115 and 116 are formed by implanting, for example, As⁺ ions into the p-type wells 104a₁ and 104a₂, and B⁺ ions into the n-type wells 104b₁ and 104b₂, and performing a heat treatment at a temperature of 800° C. for five seconds.

Thereafter, as shown in FIG. 15, sidewalls composed of a silicon nitride film 117 and a silicon oxide film 118 are formed again.

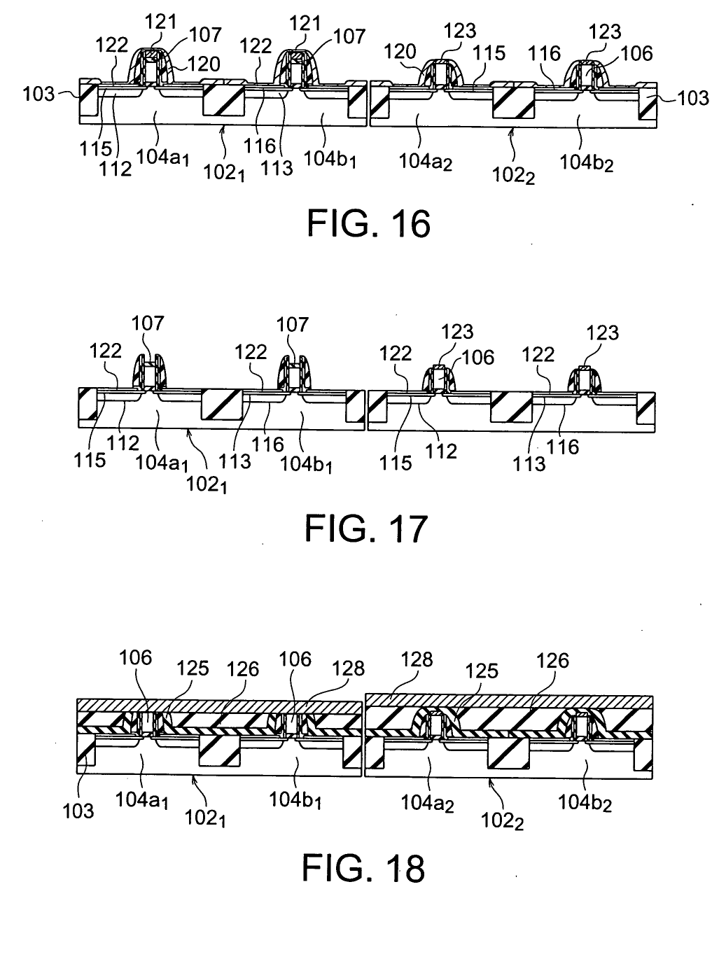

Next, as shown in FIG. 16, for example, a Ni film 120 having a film thickness of 10 nm is deposited on the entire surface, and a heat treatment is performed at a temperature of 350° C. for about 30 seconds, thereby causing Ni to react with silicon. Furthermore, as shown in FIG. 17, unreacted Ni film is removed using, for example, a mixed solution containing sulfuric acid and hydrogen peroxide. Thereafter, a heat treatment is performed at a temperature of 500° C. for about 30 seconds. Since the uppermost layer of the gate electrode in the FUSI formation region 102₁ is a thin polycrystalline silicon layer, a silicide layer is formed. When the film thickness of the polycrystalline silicon film is 0.6 or less times the film thickness of the Ni film 120, a metal-rich silicide layer 121 is formed in which the composition ratio between Ni and Si is 3 or more to 1. Since the metal-rich silicide layer 121 can be dissolved into, for example,.a mixed solution containing sulfuric acid and hydrogen peroxide, the thin polycrystalline silicon layer on the gate electrode is converted into the metal-rich silicide layer 121 and removed. As a result, a silicide layer 122 is formed only on the diffusion layers 115 and 116 (FIG. 17). The film thickness of the thin insulating film 107 can be, for example, 10 nm or less, with which it is possible to curb the diffusion of metal atoms.

On the other hand, in the non-FUSI formation region 102₂, since the gate electrode is formed of only a single layer, i.e., the polycrystalline silicon film, although the silicide layer 123 is formed, a sufficient amount of Si atoms can be supplied. Accordingly, the silicide composition cannot become metal-rich. Thus, a silicide layer 123 is also formed on the gate electrode together with the silicide layer 122 on the diffusion layers 115 and 116 without being removed by the mixed solution containing, for example, sulfuric acid and hydrogen peroxide (FIG. 17).

Then, as shown in FIG. 18, for example, a silicon nitride film 125 and an interlayer insulating film 126 are deposited on the entire surface, and the interlayer insulating film 126 is flattened by, for example, chemical mechanical polishing (CMP). Thereafter, the surface of the gate electrode is exposed by, for example, etch back only in the FUSI formation region 102₁. Then, a Ni film 128 having a film thickness of 60 nm, for example, is deposited on the entire surface.

Thereafter, as shown in FIG. 19, a heat treatment is performed in the FUSI formation region 102₁ at a temperature of, for example, 350° C. for about 30 seconds to cause the Ni film 128 to react with the polycrystalline silicon film 106. Thereafter, unreacted Ni film is removed by using, for example, a mixed solution containing sulfuric acid and hydrogen peroxide. Then, a heat treatment is performed at a temperature of 400° C. for about 30 seconds, thereby changing the polycrystalline silicon 106 of the gate electrode to a Ni silicide layer 130. On the other hand, in the non-FUSI region 102₂, since the interlayer insulating film 126and the silicon nitride film 125 are left on the gate electrode, Ni is not caused to react with the gate electrode.

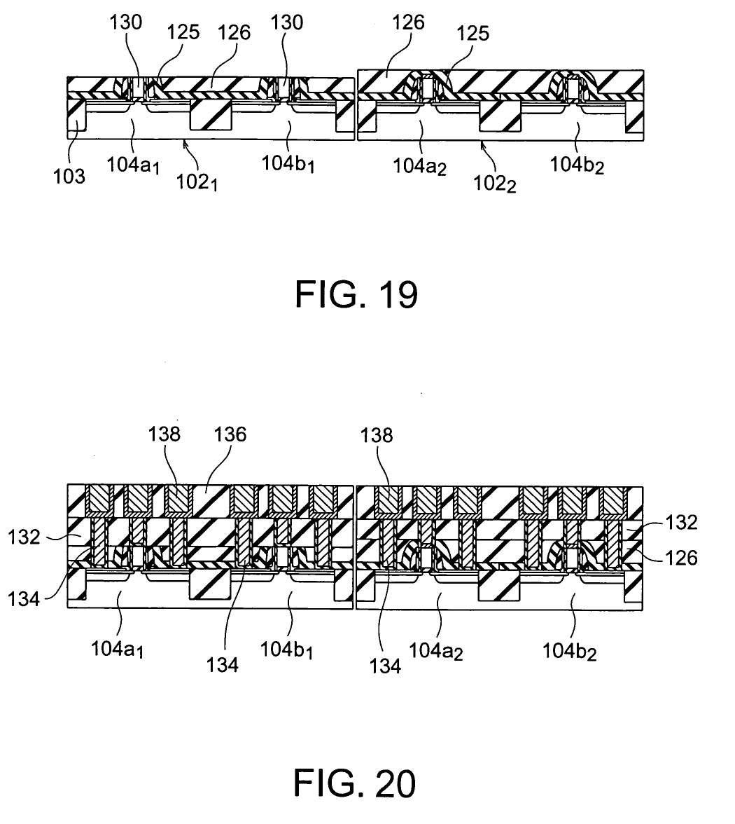

Thereafter, as shown in FIG. 20, an interlayer insulating film 132 is deposited on the entire surface, and desired contact holes are formed through the interlayer insulating films 132 and 126. Then, for example, a Ti/TiN/W film is buried in the contact holes and flattened by CMP, thereby forming contacts 134. Subsequently, an interlayer insulating film 136 is deposited on the entire surface, and a desired groove pattern is formed. Thereafter, a TaN/Cu film is buried in the groove pattern and flattened by CMP, thereby forming Cu wiring 138 electrically connecting contacts 134.

With the aforementioned process, it is possible to form a CMIS transistor having a uniformly formed silicide electrode with the shallow diffusion layer being kept.

Although a polycrystalline silicon film is used to form the gate electrode in the first and the second embodiments, germanium or a compound containing silicon and germanium can also be used. In such a case, a metal germanium compound can be used instead of a metal germanium compound.

Although polycrystalline silicon is used to form the gate electrode in the first and second embodiments, it is possible to use germanium or a compound of silicon and germanium. In this case, the gate electrode is not formed of a metal silicon compound (metal silicide) but formed of a metal germanium compound.

Furthermore, although Ni is used to form a metal suicide in the first and second embodiments, erbium (Er), thulium (Tm), palladium (Pd), platinum (Pt), cobalt (Co), rhodium (Rh), iridium (Ir), cobalt (Co) and a combination of these materials can also be used.

Moreover, although a silicon oxynitride film is formed as the gate insulating film in the first and second embodiments, the film may be a silicon oxide film or a silicon nitride film, and can be formed by any method such as thermal oxynitridation, CVD, etc.

The material of the gate insulating film is not limited to silicon oxide, but can be any material having a higher dielectric constant than silicon oxide, such as an oxide of hafnium (Hf), zirconium (Zr), titanium (Ti), tantalum (Ta), aluminum (Al), strontium (Sr), yttrium (Y), lanthanum (La), etc., and an oxide of one of these materials and silicon, such as ZrSiₓO_{y}. Furthermore, a stacked layer of these oxides can also be used.

As described above, according to the embodiments of the present invention, it is possible to obtain a semiconductor device including a MIS type transistor having a deep diffusion layer and a shallow diffusion layer as source and drain regions and a gate electrode of a metal silicide.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

1. A method of manufacturing a semiconductor device comprising:
forming a gate insulating film on a semiconductor substrate;
sequentially forming a first gate electrode material film, a first insulating film, and a second gate electrode material film, which is thinner than the first gate electrode material film, on the gate insulating film, and patterning these films and the gate insulating film to form a gate electrode;
forming a first sidewall of an insulating material at a side portion of the gate electrode;
forming a first diffusion layer in the semiconductor substrate at both sides of the gate electrode by implanting ions of an impurity using the gate electrode and the first sidewall as masks;
removing the first sidewall, and then forming a second sidewall of an insulating material, which is thinner than the first sidewall, at the side portion of the gate electrode;
forming a second diffusion layer in the semiconductor substrate at both sides of the gate electrode by implanting ions of an impurity using the gate electrode and the second sidewall as masks;
changing the second gate electrode material film of the gate electrode to a first reaction layer by forming a first metal film at least on the second gate electrode material film of the gate electrode and causing the first metal film to react with the second gate electrode material film;
removing the first reaction layer on the gate electrode;
forming an interlayer insulating film on the entire surface, and then flattening the interlayer insulating film until an upper surface of the first gate electrode material film of the gate electrode is exposed; and
forming a second metal film on the entire surface and causing the second metal film to react with the first gate electrode material film of the gate electrode, thereby changing the first gate electrode material film to a second reaction layer until the second reaction layer contacts the gate insulating film.

2. The method of manufacturing a semiconductor device according to claim 1, wherein a depth of the first diffusion layer is deeper than a depth of the second diffusion layer.

3. The method of manufacturing a semiconductor device according to claim 1, wherein the second gate electrode material film is formed of silicon or germanium, and a composition ratio of a metal from the first metal film to silicon or germanium in the first reaction layer of the second gate electrode material film is 3 or more.

4. The method of manufacturing a semiconductor device according to claim 1, wherein the first and the second metal films are formed of any of Er, Tm, Ni, Pd, Pt, Co, Rh, or Ir, or a compound thereof.

5. The method of manufacturing a semiconductor device according to claim 1, wherein when the first reaction layer is formed from the second gate electrode material film, the first metal film is also formed on the first and the second diffusion layers.

6. The method of manufacturing a semiconductor device according to claim 1, wherein the second gate electrode material film has a film thickness which is 0.6 or less times a film thickness of the first metal film.

7. A method of manufacturing a semiconductor device comprising:
forming a p-type well and an n-type well, which are element isolated, in a semiconductor substrate;
forming a first gate insulating film and a second gate insulating film on the p-type well and the n-type well, respectively;
forming a first gate electrode material film on the first and the second gate insulating films;
implanting an n-type impurity into the first gate electrode material film on the first gate insulating film, and implanting a p-type impurity into the first gate electrode material film on the second gate insulating film;
sequentially forming a first insulating film and a second gate electrode material film, which is thinner than the first gate electrode material film, on the first gate electrode material film, and patterning the second gate electrode material film, the first insulating film, the first gate electrode material film, and the gate insulating film, thereby forming a first gate electrode on the p-type well and forming a second gate electrode on the n-type well;
forming first sidewalls of an insulating material on side portions of the first and the second gate electrodes;
implanting ions of an n-type impurity using the first gate electrode and the first sidewall as masks, thereby forming a first diffusion layer of an n-type at both sides of the first gate electrode in the semiconductor substrate;
implanting ions of a p-type impurity using the second gate electrode and the first sidewall as masks, thereby forming a second diffusion layer of a p-type at both sides of the second gate electrode in the semiconductor substrate;
removing the first sidewall, and forming second sidewalls of an insulating material, which are thinner than the first sidewalls, at side portions of the first and the second gate electrodes;
implanting ions of an n-type impurity using the first gate electrode and the second sidewall as masks, thereby forming a third diffusion layer of an n-type at both sides of the first gate electrode in the semiconductor substrate;
implanting ions of a p-type impurity using the second gate electrode and the second sidewall as masks, thereby forming a fourth diffusion layer of a p-type at both sides of the second gate electrode in the semiconductor substrate;
forming a first metal film at least on the second gate electrode material film of the first and the second gate electrodes and causing the first metal film to react with the second gate electrode material film, thereby changing the second gate electrode material film of the first and the second gate electrodes to a first reaction layer;
removing the first reaction layer on the first and the second gate electrodes;
forming an interlayer insulating film on the entire surface, and flattening the interlayer insulating film until an upper surface of the first gate electrode material film of the first and the second gate electrodes is exposed; and
forming a second metal film on the entire surface, and causing the second metal film to react with the first gate electrode material film of the first and the second gate electrodes, thereby changing the first gate electrode material film to a second reaction layer to until the second reaction layer contacts the gate insulating film.

8. The method of manufacturing a semiconductor device according to claim 7, wherein a depth of the first and the second diffusion layers are deeper than a depth of the third and the fourth diffusion layers.

9. The method of manufacturing a semiconductor device according to claim 7, wherein the second gate electrode material film is formed of silicon or germanium, and a composition ratio of the metal to silicon or germanium of the first metal film in the first reaction layer of the second gate electrode material film is 3 or more.

10. The method of manufacturing a semiconductor device according to claim 7, wherein the first and the second metal films are formed of any of Er, Tm, Ni, Pd, Pt, Co, Rh, or Ir, or a compound thereof.

11. The method of manufacturing a semiconductor device according to claim 7, wherein when the first reaction layer is formed from the second gate electrode material film, the first metal film is also formed on the first to the fourth diffusion layers.

12. The method of manufacturing a semiconductor device according to claim 7, wherein the second gate electrode material film has a film thickness which is 0.6 or less times a film thickness of the first metal film.

13. A method of manufacturing a semiconductor device comprising:
forming a first semiconductor region and a second semiconductor region, which are element isolated, in a semiconductor substrate;
forming a first gate insulating film and a second gate insulating film on the first semiconductor region and the second semiconductor region, respectively;
sequentially forming a first gate electrode material film, a first insulating film, and a second gate electrode material film, which is thinner than the first gate electrode material film, on the first and the second gate insulating films;
patterning the second gate electrode material film and the first insulating film, thereby forming a pattern in an electrode shape including the second gate electrode material film and the first insulating film only on the first semiconductor region;
patterning the first gate electrode material film and the gate insulating film, thereby forming a first gate electrode including the second gate electrode material film, the first insulating film, the first gate electrode material film, and the gate insulating film on the first semiconductor region and forming a second gate electrode including the first gate electrode material film and the gate insulating film on the second semiconductor region;
forming first sidewalls of an insulating material at side portions of the first and the second gate electrodes;
implanting impurity ions using the first and the second gate electrodes and the first sidewalls as masks, thereby forming a first diffusion layer at both sides of the first and the second gate electrodes in the semiconductor substrate;
removing the first sidewalls, and forming second sidewalls of an insulating material, which are thinner than the first sidewalls, at side portions of the first and the second gate electrodes;
implanting ions of an n-type impurity using the first gate electrode and the second sidewall as masks, thereby forming a second diffusion layer at both sides of the first and the second gate electrodes in the semiconductor substrate;
forming a first metal film at least on the second gate electrode material film of the first gate electrode and the first electrode material film of the second gate electrode and causing the first metal film to react, thereby changing the second gate electrode material film of the first gate electrode to a first reaction layer and forming a second reaction layer on the first electrode material film of the second gate electrode;
removing the first reaction layer on the first gate electrode;
forming a second insulating film on the first and the second gate electrodes;
forming an interlayer insulating film on the entire surface, and flattening the interlayer insulating film until an upper surface of the first gate electrode material film of the first gate electrode is exposed in the first semiconductor region and the second insulating film on the second gate electrode is exposed in the second semiconductor region; and
forming a second metal film on the entire surface, and causing the second metal film to react with the first gate electrode material film of the first gate electrode so that the first gate electrode material film is changed to a third reaction layer until the third reaction layer contacts the gate insulating film.

14. The method of manufacturing a semiconductor device according to claim 13, wherein a depth of the first and the second diffusion layers are deeper than a depth of the third and the fourth diffusion layers.

15. The method of manufacturing a semiconductor device according to claim 13, wherein the second gate electrode material film is formed of silicon or germanium, and a composition ratio of the metal to silicon or germanium of the first metal film in the first reaction layer of the second gate electrode material film is 3 or more.

16. The method of manufacturing a semiconductor device according to claim 13, wherein the first and the second metal films are formed of any of Er, Tm, Ni, Pd, Pt, Co, Rh, or Ir, or a compound thereof.

17. The method of manufacturing a semiconductor device according to claim 13, wherein when the first reaction layer is formed from the second gate electrode material film, the first metal film is also formed on the first and the second diffusion layers.

18. The method of manufacturing a semiconductor device according to claim 13, wherein the second gate electrode material film has a film thickness which is 0.6 or less times a film thickness of the first metal film.
